(19) United States
(12) Patent Application Publication
(10) Pub. No.: US 2009/0309190 A1
(43) Pub. Date: Dec. 17, 2009

(54) SEMICONDUCTOR PROCESSING

(76) Inventors: William Andrew Nevin, Co. Armagh (GB); Alexander Holke, Sarawak (MY)

Correspondence Address: THOMPSON HINE L.L.P.;Intellectual Property Group, P.O. BOX 8801, DAYTON, OH, 45401-8801, US

(21) Appl. No.: 12/299,964

(22) PCT Filed: May 11, 2007
(86) PCT No.: PCT/GB2007/050255

§ 371 Date: Mar. 13, 2009

(30) Foreign Application Priority Data
May 11, 2006 (GB) 0609278.7

(51) Int. Cl. H01L 29/36; H01L 21/762

(52) U.S. Cl. 257/616; 438/459; 257/E29.109; 257/E21.567

(57) ABSTRACT

A semiconductor product comprises an insulator layer and a SOI (Silicon On Insulator) layer on the insulator layer, wherein the SOI layer contains implanted Germanium (Ge) at or near the interface with the insulator layer so as to form gettering sites. The semiconductor product can be manufactured by ion implanting Germanium (Ge) into silicon material and bonding the silicon material onto a handle so as to form a SOI substrate.

The present invention relates to improvements in semiconductor processing. Embodiments of the invention relate to the manufacture of a semiconductor device in a SOI (Silicon On Insulator) layer in which gettering sites are provided.

Several techniques are known to provide gettering sites in silicon substrates on which semiconductor devices are fabricated. These gettering sites are provided in order to trap impurities such as metals diffusing from outside into the silicon, for example during high-temperature processing, which can deteriorate the performance of the fabricated devices. The methods include intrinsic gettering, in which thermal treatments are used to create both a defect-free zone at the surface of the substrate wafers, where the devices are formed, and a deeper defective bulk area where impurities are gettered. Other techniques include extrinsic gettering by providing a highly doped polysilicon layer on the back surface of the wafer or by creating mechanical damage on the back surface. Alternatively, a lightly doped epitaxial layer formed on a heavily doped substrate will provide gettering by segregation at the epitaxy-substrate interface.

In bonded SOI wafers, however, these kinds of gettering techniques are not efficient because the buried oxide layer prevents the diffusion of most types of impurity out of the active silicon region into the bulk of the wafer where the gettering sites are normally formed. Therefore, the impurities remain in the SOI region and degrade devices grown using standard semiconductor device manufacturing methods. One technique to overcome this is to provide a highly doped implanted layer in the top surface of the SOI wafer, close to the devices, which will then getter impurities away from these devices. Another technique is to provide trenches around devices which can getter impurities through mechanically-induced or stress-induced defect generation in the silicon material. However, both these methods have the disadvantage that substantial extra area is needed in the device layouts to accommodate the added features, while more complex and expensive processing is also necessary.

Preferred embodiments of the present invention aim to address the disadvantages encountered with the above techniques.

Aspects of the invention are set out in the independent claims.

Preferred embodiments of the invention provide gettering sites within the SOI layer, formed during fabrication of the SOI substrate, thus enabling the efficient gettering of impurities diffusing into the SOI layer without any additional area or processing requirements for the chips.

Embodiments of the present invention provide a layer with implanted (or otherwise inserted) Ge (germanium) atoms. These are implanted (or otherwise inserted) into the surface of the device wafer before bonding to the handle, and form a gettering region in the SOI near the interface of the SOI with the buried oxide, when fabrication of the SOI is completed. The Ge sites have the ability to getter impurities diffusing through the SOI layer and trap them throughout the semiconductor processing sequence, thus enabling high quality semiconductor devices to be fabricated.

Some preferred embodiments of the invention will now be described by way of example only and with reference to the accompanying drawings, in which:

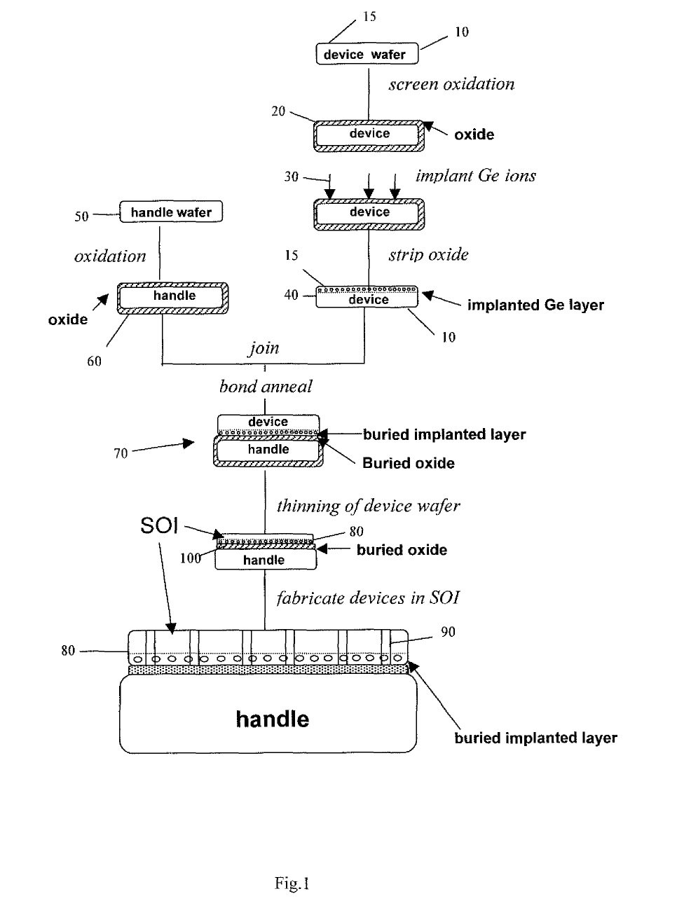

FIG. 1 illustrates a manufacturing process according to an embodiment of the present invention.

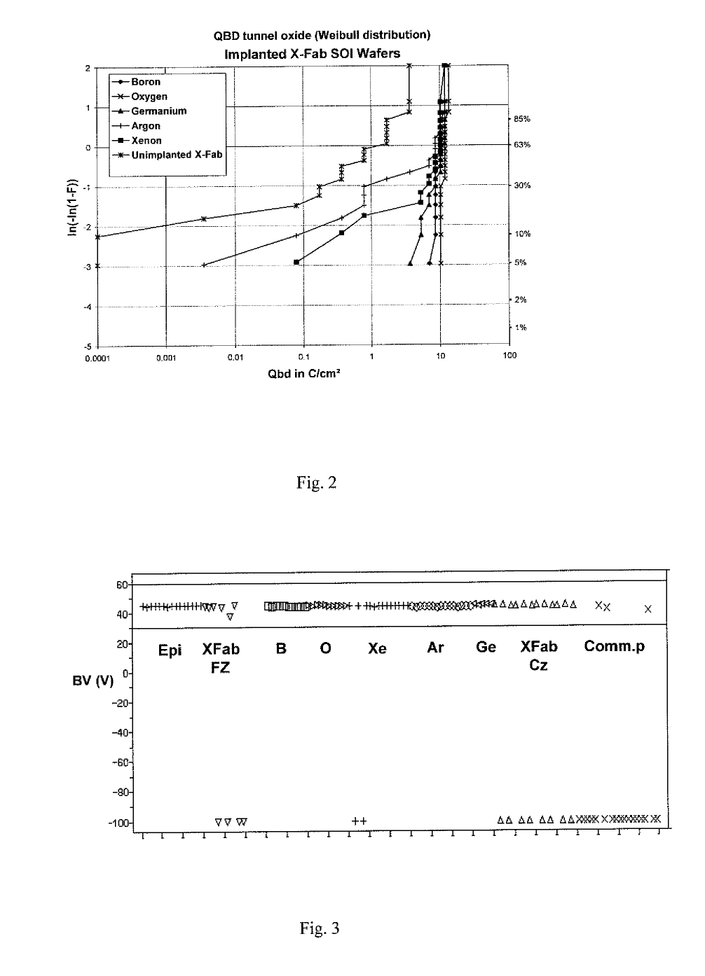

FIG. 2 shows experimental results of a semiconductor product according to an embodiment of the present invention when compared with other semiconductor products.

FIG. 3 shows experimental results of a semiconductor product according to an embodiment of the present invention when compared with other semiconductor products.

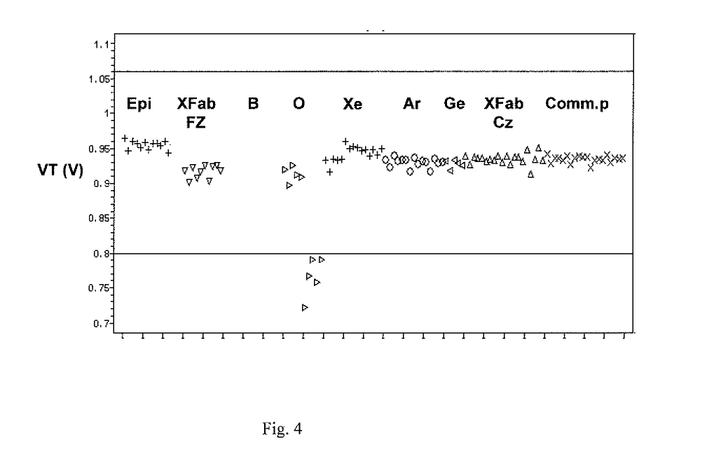

FIG. 4 shows experimental results of a semiconductor product according to an embodiment of the present invention when compared with other semiconductor products.

A first embodiment of the present invention will now be described with reference to FIG. 1. First, a (silicon) device wafer 10 is provided. The device wafer 10 has a polished surface 15. A thin screen oxide 20 is then formed by thermal oxidation or deposition. Next, Ge ions are implanted into the polished surface 15 of device wafer 10 through the thin screen oxide 20 (as indicated by arrows 30). The screen oxide 20 is then removed to reveal the device wafer 10 with an implanted Ge layer 40 at or near surface 15.

A handle wafer 50 is also provided. The handle wafer 50 is polished and oxidised so that an oxide layer 60 is formed at its surface. Next, the device wafer 10 is fusion bonded to the oxidised polished handle wafer 50. The device wafer 10 is bonded to the handle wafer 50 such that surface 15 of the device wafer 10 is closest to handle wafer 50. The bonded device and handle wafers thus form a bonded pair 70. A bond anneal may be carried out. The device wafer 10 is then thinned from the back to the required thickness. Those portions of oxide layer 60 which are located at the surface of the bonded wafer pair 70 are also removed so that only a buried oxide layer 100 remains between the handle wafer 50 and surface 15 of device wafer 10. Thus the device wafer 10 located on the buried oxide layer 100 forms a SOI wafer. The wafer contains Ge atoms in the SOI layer 80, just above the buried oxide 100, where gettering sites have been formed. Next, semiconductor devices are fabricated in the SOI layer 80, for example using trench isolation (as indicated by vertical lines 90) in combination with integrated circuit processing, and gettering takes place either through a chemical interaction between impurities and the Ge atoms or by physical interaction between impurities and damage in the silicon caused by the implantation process. Thus, high-quality devices can be formed using standard semiconductor processes.

It will be understood that the gettering sites form isolated islands in the silicon material, i.e. no substantially continuous Ge or SiGe layer is formed. The maximum extent of most (e.g. 95%), preferably of all, isolated islands in any direction is preferably less than 50 nm, more preferably less than 30 nm and most preferably less than 10 nm.

In an alternative embodiment, which generally follows the same sequence as the first embodiment, the oxide layer 20 on device wafer 10 is not stripped before the joining of the device wafer 10 to handle wafer 50. In this case the handle wafer 50 may be either oxidised or unoxidised.

In a third embodiment, which again generally follows the sequence of the first embodiment, the screen oxide layer 20 is stripped, but another oxide layer is formed on the device wafer 10 prior to joining to handle wafer 50. Again, in this case handle wafer 50 may be oxidised or unoxidised.

In each of the above embodiments, the Ge could be inserted into the silicon by other means, for example by gaseous diffusion of Ge atoms.

Examples of results of the invention are shown in FIGS. 2-4. FIG. 2 compares Qbd plots for 9 nm thick tunnel oxides, grown during an integrated circuit production process on standard SOI wafers without a buried gettering layer (“unimplanted X-Fab”), with oxides grown on SOI containing gettering layers of various implanted species. For all implanted species the implantation dose was about 5-10e15 ions/cm², at about 80 keV. Qbd is a measure of the quality of the oxide, with higher values being indicative of better quality. It can be seen that the standard SOI give very poor quality oxides, those with argon and xenon implants show better quality, while the best quality is seen for germanium, oxygen and boron implants.

FIG. 3 shows breakdown voltages for 40 nm thick gate oxides grown on SOI with and without buried implanted layers. In FIG. 3, each column relates to a particular type of material, and symbols such as “+” and “□” are used to indicate a measurement result associated with the type of material in the same column. “B”, “O”, “Xe”, “Ar” and “Ge” again stand for SOI implanted with boron, oxygen etc.

“Epi” means standard epitaxial substrate, i.e. not SOI. This is expected to give a good oxide since internal gettering can occur. This material is therefore used as a quality benchmark.

“XFab FZ” and “XFab CZ” are unimplanted SOI samples produced by X-Fab Semiconductor Foundries AG, whereby “FZ” and “CZ” refer to the handle silicon material type (Float Zone or Czochralski). “Comm.p.” stands for a commercially available unimplanted SOI produced by a third party.

The oxides for SOI with implanted layers show excellent quality and yield, while those on standard SOI have poor yields. By way of explanation, each symbol represents a measurement point taken at certain standard positions across a wafer. Symbols at about 40 V means that the oxides have broken down electrically at about 40 V applied bias for these positions, which indicates good quality. Those at −100V show points which have broken down at low voltages and so indicate poor oxide in these positions. The wafers have varying amounts of good and bad points, depending on the wafer yield, e.g. Ge is 100% good, while XFab FZ has only about 50% of the measurement points good.

FIG. 4 shows an example of a typical device parameter for devices fabricated on various SOI wafers. The results for boron and oxygen implants show some perturbation of the device parameters, probably due to up-diffusion of the implanted species into the active device regions, which will alter the doping profiles and/or result in the formation of defects in the silicon. Note that for boron the perturbation is so strong that the values are off the scale of FIG. 4. In contrast, germanium, argon and xenon implanted wafers give similar parameters to the standard SOI.

From a synopsis of FIGS. 2 to 4 it will be apparent that germanium is the most advantageous species for forming the buried gettering region, since it both improves the oxide quality but does not perturb the device parameters.

Although the invention has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the invention, whether alone or in any appropriate combination with any other feature disclosed or illustrated herein.

1. A semiconductor product comprising:
an insulator layer; and
a SOI (Silicon On Insulator) layer on the insulator layer,
wherein the SOI layer contains Germanium (Ge) at or near the interface with the insulator layer.

2. A semiconductor product according to claim 1, wherein the Ge is arranged to form gettering sites.

3. A semiconductor product according to claim 2, wherein the gettering sites form isolated islands.

4. A semiconductor product according to claim 3, wherein the isolated islands have a maximum diameter of less than 50 nm.

5. A semiconductor product according to claim 1, wherein a peak Ge concentration is located within a layer of the SOI layer closest to the insulator layer, and wherein said layer is less than 50% as thick as the SOI layer.

6. A semiconductor product according to claim 1, wherein 95% of the Ge is located within a layer-like region of the SOI layer closest to the insulator layer, and wherein said region is less than 50% as thick as the SOI layer.

7. A semiconductor product according to claim 6, wherein the Ge content in the layer-like region is less than 1%.

8. A semiconductor product according to claim 1, wherein the Ge is provided in the form of implanted ions.

9. A semiconductor product according to claim 8, wherein the ions have been implanted with an implanting dose less than 1e18 ions/cm².

10. A semiconductor product according to claim 8, wherein the ions have been implanted through that surface of the silicon material of the SOI layer which, in the semiconductor product, is closest to the insulator layer.

11. A semiconductor product according to claim 1, wherein the insulator layer comprises an oxide layer.

12. A semiconductor product according to claim 1, wherein the semiconductor product has been made by bonding Ge containing silicon material onto a handle so as to form said SOI layer.

13. A method comprising using Germanium as gettering substance in a SOI layer at or near the interface of the SOI layer with an insulator layer.

14. A method of manufacturing a semiconductor product, comprising:
inserting Germanium (Ge) into silicon material; and
bonding the silicon material onto a handle so as to form a SOI substrate.

15. A method according to claim 14, wherein the Ge forms gettering sites.

16. A method according to claim 15, wherein the gettering sites form isolated islands.

17. A method according to claim 14, wherein inserting the Ge comprises inserting the Ge into, or through, the surface of the silicon material.

18. A method according to claim 17, wherein bonding the silicon material onto the handle comprises bonding onto the handle that surface of the silicon material into, or through, which the Ge has been inserted.

19. A method according to claim 14, wherein inserting the Ge comprises implanting Ge ions into the silicon material.

20. A method according to claim 19, wherein implanting the Ge ions comprises implanting the Ge ions with an implanting dose less than 1e18 ions/cm².

21. A method according to claim 14, wherein the silicon material comprises a device wafer and/or the handle comprises a handle wafer.

22. A method according to claim 21, wherein the handle wafer comprises silicon.

23. A method according to claim 21, further comprising thinning the device wafer.

24. A method according to claim 14, further comprising annealing the bonded pair comprising the silicon material bonded onto the handle.

25. A method according to claim 14, further comprising forming a semiconductor device in the SOI substrate.
